(19) United States
(12) Patent Application Publication
(10) Pub. No.: US 2004/0075099 A1
(43) Pub. Date: Apr. 22, 2004

(54) Position detecting method and apparatus

(76) Inventors: Takahiro Matsumoto, Tochigi (JP); Hideki Ina, Kanagawa (JP)

Correspondence Address: MORGAN & FINNEGAN, L.L.P., 345 PARK AVENUE, NEW YORK, NY, 10154, US

(21) Appl. No.: 10/665,100

(22) Filed: Sep. 18, 2003

(30) Foreign Application Priority Data
Sep. 20, 2002 (JP) 2002-275823

(51) Int. Cl. H01L 47/00; H01L 33/00

(52) U.S. Cl. 257/98; 257/3

(57) ABSTRACT

Signal processing is set at step S51. Image information concerning an alignment mark is acquired and calculated from an alignment detecting optical system at step S53. The amount of positional deviation is calculated at step S54 by the signal processing, which was set at step S51, from the alignment-mark image information acquired at step S53. A combination of a shot (position information) and signal processing for which a residual error Ri will be minimized is obtained at step S57, a wafer is positioned in a projection optical system at step S58 by a wafer stage based upon AGA parameters calculated in accordance with the conditions of this minimizing combination, and the pattern on a reticle is transferred to the wafer by exposure at step S59.

### FIELD OF THE INVENTION

This invention relates to position detecting method and apparatus effective in aligning a wafer or reticle in a semiconductor exposure apparatus, by way of example.

### BACKGROUND OF THE INVENTION

In a projection-type exposure apparatus utilized in the manufacture of various devices, e.g., semiconductor chips such as IC and LSI chips, display elements such as liquid crystal panels, detecting elements such as magnetic heads, and image sensors such as CCDs, an increase in the fineness and density of the circuits used in these devices has been accompanied by the need to project a circuit pattern on the surface of a reticle onto the surface of a wafer, to thereby expose the wafer to the pattern, at a higher resolution.

Since the projection resolution of a circuit pattern depends upon the NA (numerical aperture) of the projection optical system and the wavelength of the exposing light, a method of enlarging the NA of the projection optical system or a method of shortening the wavelength of the exposing light has been adopted as a method of raising resolution. In relation to the latter method, a shift from g rays to i rays and from i rays to an excimer laser is in progress in regard to the exposing light source. Exposure systems based upon excimer lasers having lasing wavelengths of 248 nm and 193 nm have already been put into practical use.

Exposure systems of even shorter lasing wavelengths, namely a VUV exposure system having a wavelength of 157 nm and an EUV exposure system having a wavelength of 13 nm, are being studied as candidates for next-generation exposure systems.

Further, processes for manufacturing semiconductor devices have become highly diversified, and methods such as CMP (Chemical Mechanical Polishing) have been introduced as flattening techniques for solving the problem of inadequate focal depth encountered in exposure systems.

Structures and materials of semiconductor devices also are multifarious. For example, a P-HEMT (Pseudomorphic High Electron Mobility Transistor) and an M-HEMT (Metamorphe-HEMT), which are obtained by combining compounds such as GaAs and InP, etc., and an HBT (Heterojunction Bipolar Transistor), which employs SiGe or SiGeC, have been proposed.

Meanwhile, finer circuit patterns have led to the need for highly precise alignment of the reticle, on which the circuit pattern is formed, and the wafer, onto which the circuit pattern is projected. The required precision is ⅓ of the circuit line width. For example, the required precision in current 180-nm designs is 60 nm, or ⅓ of 180.

Alignment in an exposure apparatus is carried out by exposing a wafer to the circuit pattern on a reticle and alignment marks simultaneously to transfer the circuit pattern and alignment marks, detecting the position of the alignment marks optically when the wafer is exposed to the circuit pattern of the next reticle, and positioning the wafer with respect to the reticle. Methods of detecting an alignment mark include a method of capturing the image of the alignment mark upon enlarging the image by a microscope, and then detecting the position of the mark image, and a method of using a diffraction grating as an alignment mark, detecting the phase of an interference signal that interferes with the diffracted light, and detecting the position of the diffraction grating.

The state of the art in the semiconductor industry is such that raising overlay accuracy for aligning the design pattern of the next step and the circuit pattern already on the wafer is essential for the purpose of improving the performance of semiconductor devices and the yield of manufacture insofar as an exposure apparatus is used. However, owing to the introduction of special semiconductor manufacturing techniques such as the CMP process, the structure of circuit patterns has been improved but a frequently occurring problem is the occurrence of a variation in the shape of the alignment marks between wafers or between shots and an attendant decline in alignment precision.

It is believed that a cause of asymmetry in the structure of alignment marks is that an increase in the fineness of circuit patterns is accompanied by a greater difference between the line width of the circuit pattern and the line width of the alignment mark. Process conditions relating to film formation, etching and CMP, etc., are optimized to the line width of the circuit pattern (a line width of 0.1 to 0.15 μm), and therefore a mark structure having a line width the same as that of a circuit pattern would not exhibit much asymmetry. However, since an alignment mark having a line width (a line width of 0.6 to 4.0 μm) that is large in comparison with that of the a circuit pattern departs from the process conditions, there are cases where the structure of the mark becomes asymmetric.

When it is attempted to make the line width of an alignment mark conform to the line width of a circuit pattern, there is a decline in signal strength or contrast because the resolution of the detection optical system used in alignment is inadequate. The result is a decline in the stability of the alignment-mark detection signal. In order to realize a detection optical system capable of detecting an alignment mark having a line width equivalent to that of a circuit pattern, a large NA and a light source having a short wavelength are required. This necessitates a detection optical system equivalent to that of a projection optical system and therefore gives rise to a new problem, namely an increase in the cost of the apparatus.

In view of these circumstances, efforts have been made to change process conditions so as to thereby obtain conditions suited to both the alignment mark and circuit pattern. To achieve this, conditions are set by trial and error, or various types of alignment marks having different line widths are fabricated, exposure is evaluated and use is made of the alignment mark whose line width is deemed to be best.

Accordingly, an enormous amount of time is required to decide the optimum conditions (parameters). Further, a process error, for example, may occur after parameters have been decided. In such case it may be necessary to alter the parameters of the exposure apparatus to follow up a modification in the manufacturing process in response to the process error. Altering the parameters takes a great deal of time.

In the future, moreover, further progress will be made in producing finer circuit patterns, new semiconductor processes will be introduced and wafers of larger diameter (on the order of 300 mm) will be used. As a result, it is predicted that it will be increasingly difficult to fabricate both circuit patterns and alignment marks that are defect-free over the entire surface of a wafer.

### SUMMARY OF THE INVENTION

Accordingly, an object of the present invention is to provide a position detection method and apparatus capable of performing high-precision detection without detracting from the precision of alignment-mark detection even in a case where there is an error in the position of an alignment mark formed on a wafer.

According to the present invention, the foregoing object is attained by providing a position detection method for detecting the position of an object upon receiving light from a plurality of position detection marks on the object, comprising: an image information acquisition step of obtaining image information of every position detection mark from the light that has been received; a position information calculation step, which has a plurality of calculation processes, of calculating position information of every position detection mark from the image information using a prescribed calculation process among the plurality of calculation processes; an error information calculation step of calculating information representing an error of a position detection mark, which corresponds to each item of the position information, with respect to a reference position; a residual-error information calculation step of calculating information representing a residual error that is the result of eliminating a prescribed error component from the information representing the error; a storage step of finding, for each item of the position information, a calculation process, from among the plurality of calculation processes, for calculating pertinent position information that will minimize the residual error, and storing a combination of this position information and calculation process that corresponds thereto; and a position detection step of detecting the position of the object using information representing an error calculated based upon the combination of the position information and the calculation process that corresponds thereto.

Further, according to the present invention, the foregoing object is attained by providing a position detection apparatus for detecting the position of an object upon receiving light from a plurality of position detection marks on the object, comprising: an image information acquisition unit for obtaining image information of every position detection mark from the light that has been received; a position information calculation unit, which has a plurality of calculation processes, for calculating position information of every position detection mark from the image information using a prescribed calculation process among the plurality of calculation processes; an error information calculation unit for calculating information representing an error of a position detection mark, which corresponds to each item of the position information, with respect to a reference position; a residual-error information calculation unit for calculating information representing a residual error that is the result of eliminating a prescribed error component from the information representing the error; a storage unit for finding, for each item of the position information, a calculation process, from among the plurality of calculation processes, for calculating pertinent position information that will minimize the residual error, and storing a combination of this position information and calculation process that corresponds thereto; and a position detection unit for detecting the position of the object using information representing an error calculated based upon the combination of the position information and the calculation process that corresponds thereto.

An exposure apparatus according to the present invention has a stage device driven in order to position the object based upon position information detected by the above-described position detection apparatus, the stage device positioning a substrate or a reticle or both as the object.

Thus, in accordance with the present invention, as described above, an optimum signal processing method is selected automatically in dependence upon the structure of an alignment mark even in a case where there is a variation in the structure of alignment marks between shots in execution of global alignment. As a result, the invention is not readily susceptible to the effects of a variation in alignment-mark structure, etc., ascribable to the semiconductor process. This makes it possible to improve alignment precision and to raise yield in a process for manufacturing semiconductor devices. Further, the productivity of semiconductor-device manufacture can be improved because it is possible to shorten the time needed to determine semiconductor-process conditions necessary to stabilize alignment-mark shape.

Other objects and advantages besides those discussed above shall be apparent to those skilled in the art from the description of a preferred embodiment of the invention which follows. In the description, reference is made to accompanying drawings, which form a part thereof, and which illustrate an example of the invention. Such example, however, is not exhaustive of the various embodiments of the invention, and therefore reference is made to the claims which follow the description for determining the scope of the invention.

### BRIEF DESCRIPTION OF THE DRAWINGS

FIG. 1 is a schematic view illustrating a semiconductor exposure apparatus according to an embodiment of the present invention;

FIG. 2 is a schematic view illustrating an alignment detecting optical system according to this embodiment;

FIG. 3 is a diagram illustrating a method of detecting alignment-mark position according to a first embodiment of the present invention;

FIG. 4 is a diagram illustrating a method of detecting alignment-mark position according to a second embodiment of the present invention;

FIG. 5 is a diagram exemplifying an alignment-mark detection signal;

FIG. 6 is a diagram illustrating templates used in detecting alignment-mark position according to the first embodiment;

FIG. 7 is a diagram exemplifying the manner in which an alignment-mark detection signal varies between shots;

FIG. 8 is a diagram illustrating signal processing in detection of alignment-mark position according to the first embodiment;

FIG. 9 is a diagram useful in describing global alignment;

FIG. 10 is a diagram illustrating a linear coordinate transformation and residual error;

FIG. 11 is a diagram illustrating AGA parameters and residual-error calculation conditions according to the first embodiment;

FIG. 12 is a flowchart illustrating processing for detecting alignment-mark position according to the first embodiment;

FIG. 13 is a diagram illustrating signal processing in a method of detecting alignment-mark position according to the second embodiment;

FIG. 14 is a diagram illustrating signal processing in a method of detecting alignment-mark position according to a third embodiment of the present invention;

FIG. 15 is a flowchart useful in describing the flow of a device manufacturing process that uses the exposure apparatus according to this embodiment; and

FIG. 16 is a diagram useful in describing a wafer process that uses the exposure apparatus according to this embodiment.

### DETAILED DESCRIPTION OF THE PREFERRED EMBODIMENTS

Preferred embodiments of the present invention will now be described with reference to the accompanying drawings.

[Structure of Exposure Apparatus]

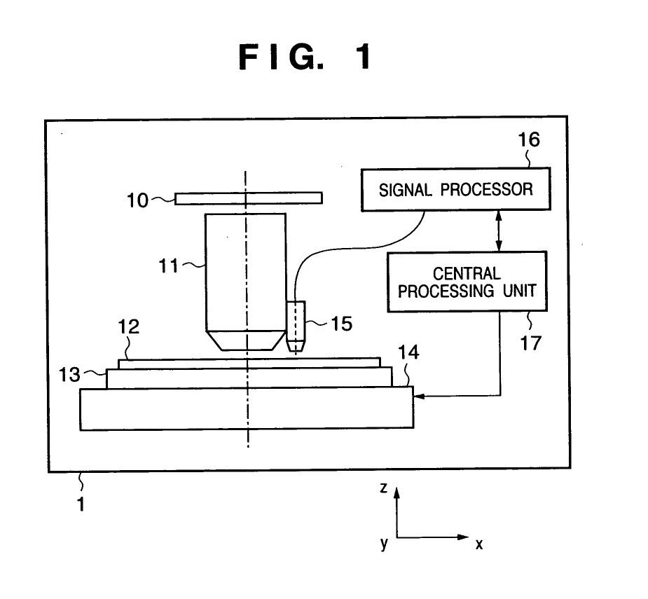

FIG. 1 is a schematic view illustrating a semiconductor exposure apparatus according to this embodiment of the present invention.

As shown in FIG. 1, a semiconductor exposure apparatus (referred to also as an exposure apparatus below) 1 comprises a projection optical system 11 for demagnifying and projecting a reticle 10 on which a predetermined circuit pattern has been formed; a wafer chuck 13 for holding a wafer 12 on which a base pattern and an alignment mark have been formed by a preceding step; a wafer stage 14 for positioning the wafer 12 at a predetermined position (alignment position); and an alignment detecting optical system (alignment scope) 15 for detecting the position of the alignment mark that has been formed on the wafer 12.

The principle for detecting an alignment mark by the alignment detecting optical system 15 will now be described.

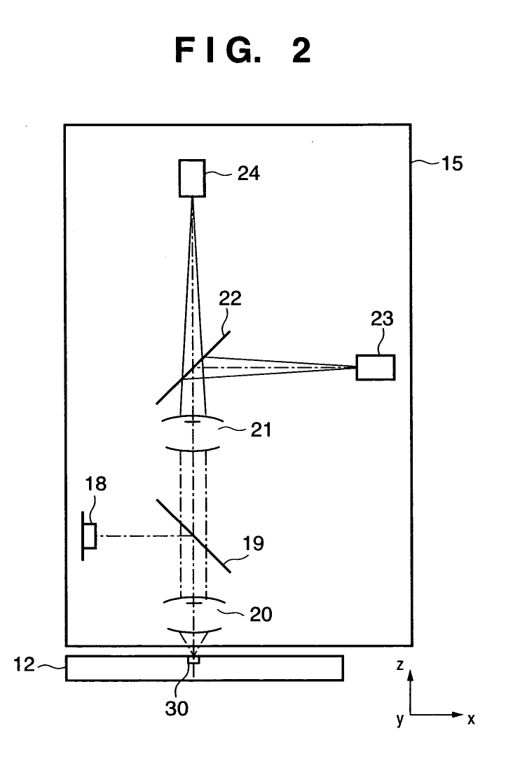

FIG. 2 is a schematic view illustrating the main structural components of the alignment detecting optical system 15.

As shown in FIG. 2, illuminating light from a light source 18 is reflected by a beam splitter 19, impinges upon a lens 20 and illuminates an alignment mark 30 on the wafer 12 from the lens 20. Diffracted light from the alignment mark 30 passes through the lens 20, beam splitter 19 and a lens 21 and is split by a beam splitter 22, and the split beams are received by respective ones of image sensors 23, 24. The alignment mark 30 is enlarged at an image-forming magnification on the order of 100×by the lenses 20 and 21 and the enlarged image is formed on the image sensors 23, 24. The image sensors 23 and 24 are used to detect a shift in the position of the alignment mark 30 along the X and Y directions, respectively, and are placed at an angle of approximately 90° with respect to the optic axis. Though not illustrated, a cylindrical lens having power only in the direction perpendicular to the alignment-mark detection direction is provided, and light is gathered in the direction perpendicular to the mark detection direction by this lens, whereby optical integration and averaging take place.

The image sensors 23, 24 send a signal processor 16 an image pick-up signal obtained by photo electric converting the optical image of the alignment mark 30. On the basis of the image pick-up signal, the signal processor 16 calculates position information representing the alignment mark 30. A central processing unit 17 positions the wafer stage 14 so as to correct positional deviation of the wafer based upon the position information calculated by the signal processor 16.

[First Embodiment]

A method of detecting the position of an alignment mark according to a first embodiment will be described next.

Since the principle through which the position of an alignment mark is detected in the X direction is the same as that in the Y direction, only the method of detecting the position of the alignment mark in the X direction will be described.

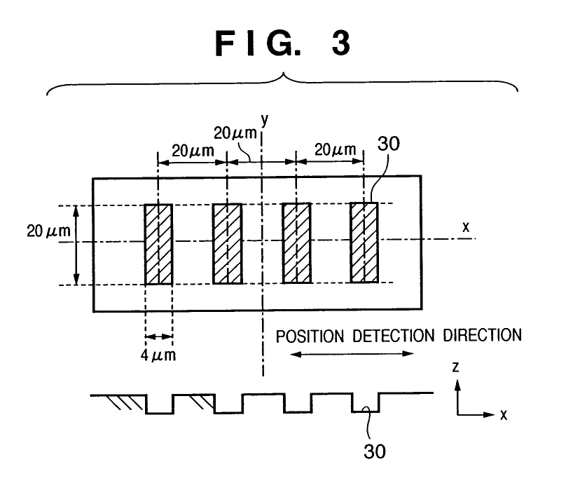

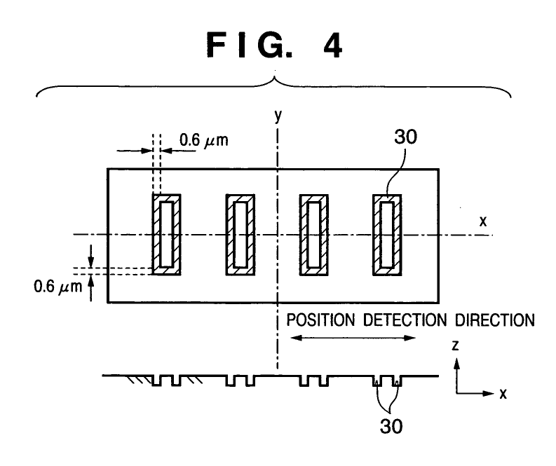

A mark having a shape of the kind shown in FIG. 3 or FIG. 4 is used as the alignment mark 30. In FIG. 3, four rectangular marks each having a length of 4 μm in the X direction, which is the mark detection direction, and a length 20 μm in the Y direction, which is substantially orthogonal to the mark detection direction, are arrayed at intervals of 20 μm in the X direction. The cross section of the mark is made concave by etching. In actuality, the mark is coated with a resist, though this is not illustrated. In FIG. 4, on the other hand, each mark has a shape obtained by forming an edge portion having a line width of 0.6 μm on the exterior of the marks shown in FIG. 3.

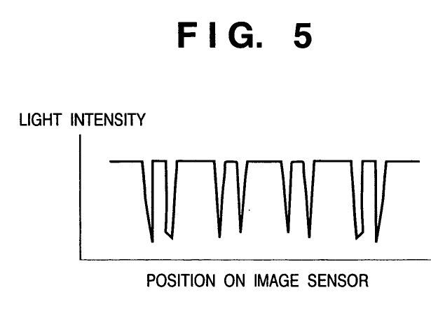

Even if alignment marks of the kind shown in FIG. 3 or 4 are used, a large angle that will not fall within the NA of the lenses in the alignment detecting optical system 15 is obtained, and image information picked up by the image sensor 23 becomes as shown in FIG. 5 owing to the occurrence of scattered light at the edges of the marks and interference with the scattered light at the edges of the marks. Further, the edge portions of the alignment marks of FIG. 3 appear dark, while the concave portions of the alignment marks in FIG. 4 appear dark or light. This is a characterizing feature of an image often observed in bright field images.

The image information representing the alignment mark thus sensed is processed by the signal processor 16 in the manner described below.

The image sensors 23, 24 of this embodiment are CCD cameras that capture one-dimensional line-image information or two-dimensional image information of the alignment mark 30.

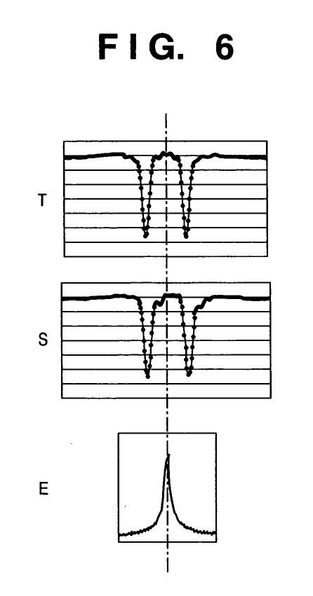

A template matching method is used to calculate alignment-mark position information according to this embodiment. Template matching calculates the correlation between a sensed-image signal, which represents image information indicated at S in FIG. 6, and a template (indicated at T in FIG. 6) retained beforehand on the apparatus side. Position information exhibiting the highest correlation is detected as the center position of the alignment mark. By obtaining the position of a centroid pixel of an area of several pixels to the left and right of a peak pixel in a function of correlation values illustrated at E in FIG. 6, a resolution of 1/10 to 1/50 pixel can be achieved.

An arithmetic equation used in template matching is represented by Equation (1) below.

$$E ( X ) = \frac{1}{{\sum }_{J = - k}^{k} {\vert S ( X + J ) - T ( J ) \vert}^{2}} \qquad ( 1 )$$

where S represents an image signal sensed by the image sensor, T a template and E the result of correlation.

The relationship among the signal S, template T and correlation value E becomes as shown in FIG. 6 when illustrated. FIG. 6 illustrates processing relating to image information concerning a single alignment mark among the four alignment marks. Similarly, in regard to the image information representing the three other alignment marks, each item of position information is detected from each item of image information sensed by the image sensor by means of the template matching method.

First, position information X1(n), X2(n), X3(n), X4(n) of image information relating to the alignment marks is found by the template matching method (the units are pixels), where n represents the template number. Thereafter, the average position of the alignment marks is found from Equation (2) below.

Xa(n)=[X1(n)+X2(n)+X3(n)+X4(n)]/4 (2)

A deviation Xw(n) in the position of the alignment mark 30 from the sensed-image signal of each image sensor is obtained as

Xw(n)=Xa(n)/(Px·M) (3)

where M represents the image forming magnification of the alignment detecting optical system 15 and Px the pixel pitch in the direction in which the alignment marks are detected by the image sensor 23.

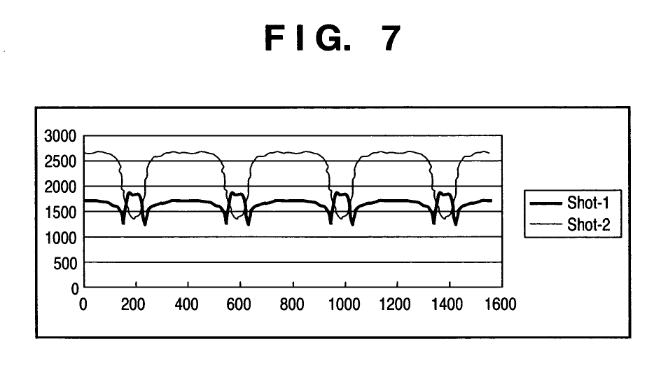

FIG. 7 illustrates the sensed-image signal waveforms of actual alignment marks acquired at a step in a semiconductor manufacturing process. Two signals are mixed, namely a signal (a double-peak signal) having two minimal values conforming to both ends of a single alignment mark (bar mark), and a signal (a single-peak signal) having a minimal value only in the vicinity of the center of the alignment mark, this depending upon the shot position on the wafer. In FIG. 7, Shot 1 represents the double-peak signal and Shot 2 represents the single-peak signal.

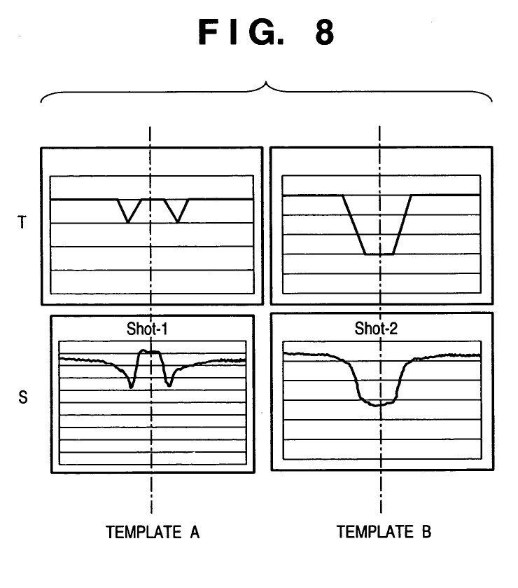

In this case, as depicted in FIG. 8, mark position can be detected in highly accurate fashion by using template A, which is suited to the double peak, for the double-peak signal, and using template B, which is suited to the single peak, for the single-peak signal.

According to this embodiment, positional deviation Xw(n) of an alignment mark from the position information calculated with each of the templates (template number n) from Equations (1), (2), (3) is obtained using the two types of templates, namely template A (template number 1) and template B (template number 2) with regard to the image information of the alignment calculated as described above, and Xw(n) is stored temporarily in a memory within the signal processor 16.

Next, a method of aligning a wafer from positional deviation of the alignment mark calculated as set forth above will be described.

Global alignment (AGA) is applied in this embodiment. With global alignment, several shots are selected from among all chips (shots) on a wafer (a selected shot shall be referred to as a “sample shot”), and position information concerning an alignment mark among the selected shots is detected.

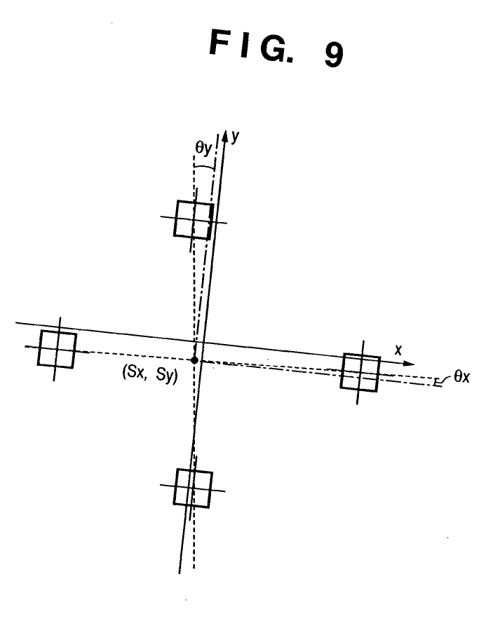

FIG. 9 illustrates the manner in which an array of shots on a wafer has deviated with respect to the xy coordinate system of the wafer stage in the above-described exposure apparatus 1. The deviation in the position of the wafer can be described by six parameters, namely shift Sx in the x direction, shift Sy in the y direction, inclination θx with respect to the x axis, inclination θy with respect to the y axis, magnification Bx along the x direction and magnification By along the y direction. The magnifications Bx, By represent expansion and contraction of the wafer with the direction in which the wafer stage of the exposure apparatus is fed serving as a reference. This expansion and contraction of the wafer is caused by film formation and etching in the semiconductor process.

Let position information of each sample shot of AGA detected as set forth above be described as Ai (where i is the detected shot number), namely,

$$A i = ( \begin{matrix}x i \\ y i\end{matrix} ) \qquad ( 4 )$$

and let designed position coordinates of an alignment mark of a sample shot be described as Di, namely

$$D i = ( \begin{matrix}X i \\ Y i\end{matrix} ) \qquad ( 5 )$$

In AGA, the following linear coordinate transformation D′i is performed using the six parameters (Sx, Sy, θx, θy, Bx, By) representing the positional deviation of the wafer cited earlier:

$${D}^{′} i = ( \begin{matrix}B x & - θ y \\ θ x & B y\end{matrix} ) D i + ( \begin{matrix}S x \\ S y\end{matrix} ) \qquad ( 6 )$$

In Equation (6) above, θx, θy, are assumed to be small for the sake of simplicity and Bx≈1, By≈1, and therefore use is made of approximation equations such as cos θ=1, sin θ=0, θx*Bx=θx, θy*By=θy.

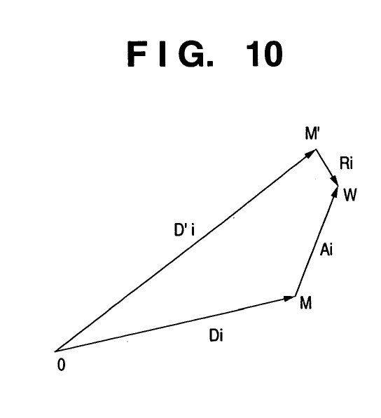

FIG. 10 illustrates the manner in which the linear coordinate transformation of Equation (6) is performed. An alignment mark on a wafer is located at the position indicated by W in FIG. 10. This is a deviation of Ai from the position of point M, which is the designed position. If the coordinate transformation D′i is carried out, the positional deviation (residual error) of the alignment mark on the wafer is calculated using Equation (7) below.

Ri=(Di+Ai)D′i (7)

According to AGA, the method of least squares is applied so as to minimize the residual error Ri of each sample shot, and AGA parameters (Sx, Sy, θx, θy, Bx, By) that will minimize the mean sum of the squares of the residual error Ri are calculated.

$$\begin{matrix}{V = \frac{1}{n} \sum \vert R i \vert}^{2} \\ \frac{1}{n} {\sum }_{i = 1}^{i = n} {\vert ( \begin{matrix}x i \\ y i\end{matrix} ) - ( \begin{matrix}B x - 1 & - θ y \\ θ x & B y - 1\end{matrix} ) ( \begin{matrix}X i \\ Y i\end{matrix} ) + ( \begin{matrix}S x \\ S y\end{matrix} ) \vert}^{2} & ( 8 ) \\ ( \begin{matrix}\begin{matrix}\begin{matrix}\begin{matrix}\begin{matrix}δ V / δ S x \\ δ V / δ S y\end{matrix} \\ δ V / δ θ x\end{matrix} \\ δ V / δ θ y\end{matrix} \\ δ V / δ B x\end{matrix} \\ δ V / δ B y\end{matrix} ) = 0 & ( 9 )\end{matrix}$$

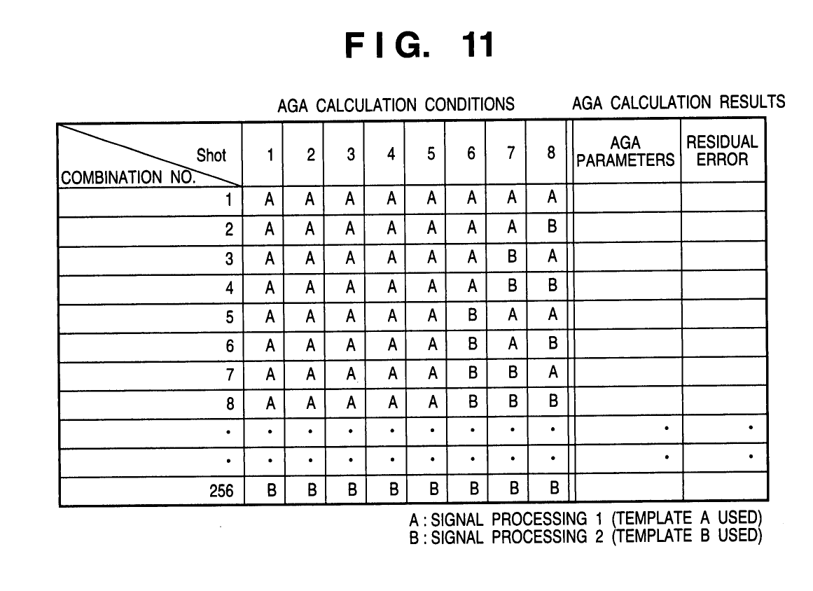

The AGA parameters (Sx, Sy, θx, θy, Bx, By) are found by substituting the position information (xi,yi) of the alignment mark of each sample shot and the alignment-mark designed position (Xi,Yi) into Equations (8) and (9) cited above, and the residual error Ri is found from Equation (7) above. These calculations are performed with regard to all sample shots and signal processing (templates A and B). That is, the AGA parameters and residual error are calculated under 256 conditions, as shown in FIG. 11, and the results of these calculations are stored in memory classified according to combination number.

Next, a combination number that will minimize the residual error is selected from FIG. 11, positioning of each shot is performed based upon these AGA parameters, and the pattern on the reticle is transferred to the wafer by exposure.

The reason for using a combination that will minimize the residual error is as follows: Residual error is the sum of non-linear distortion caused by the semiconductor process and detection error involving the alignment mark. Since the non-linear distortion component is approximately constant for the same wafer, the smaller the residual error, the greater the alignment-mark detection precision. It should be noted that calculation results involving ten combination numbers may be obtained from those for which the residual errors are small, and the average value of these results may be used to correct the AGA position.

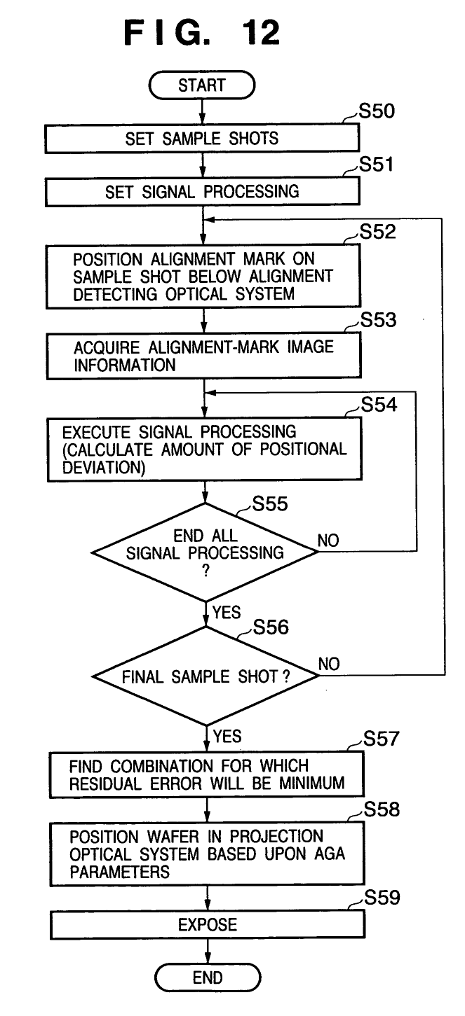

Finally, a method of detecting the position of an alignment mark according to this embodiment will be described with reference to the flowchart of FIG. 12.

At step S50 in FIG. 12, which shots on a wafer are to be made alignment-mark detection shots in AGA is set.

Next, the type of signal processing is set at step S51. (In this embodiment, the template matching method using templates A and B is applied.)

An alignment mark among the sample shots on the wafer mounted on the wafer stage is positioned below the alignment detecting optical system at step S52.

Image information concerning the alignment mark is acquired and calculated from the alignment detecting optical system at step S53.

The amount of positional deviation is calculated at step S54 by the signal processing, which was set at step S51, from the alignment-mark image information acquired at step S53.

Whether the amount of positional deviation has been calculated is determined at step S55 with regard to all signal processing set at step S51. If there is signal processing for which calculation has not been performed (“NO” at step S55), control returns to step S54 and the amount of positional deviation is calculated by the remaining signal processing.

If all signal processing is terminated (“YES” at step S55), then it is determined at step S56 whether a sample shot to be detected still remains among the sample shots set at step S50. If a sample shot still remains (“NO” at step S56), control returns to step S52 and the processing of steps S52 to S55 is executed with regard to all of the sample shots that were set at step S50.

If all sample shots are found to be finished (“YES” at step S56), then a combination of a shot (position information) and signal processing for which the residual error Ri will be minimized is obtained at step S57, the wafer is positioned in projection optical system at step S58 by the wafer stage based upon the AGA parameters calculated in accordance with the conditions of this minimizing combination, and the pattern on the reticle is transferred to the wafer by exposure at step S59.

[Second Embodiment]

A method of detecting alignment-mark position according to a second embodiment will now be described.

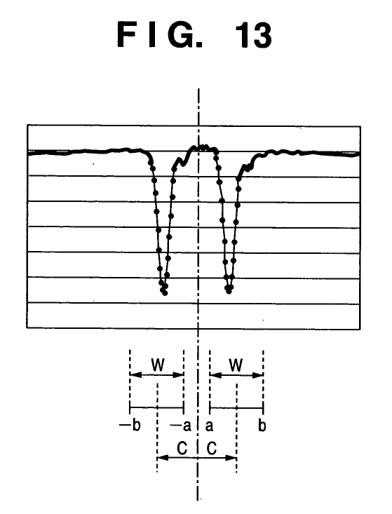

The shape of the alignment mark and the alignment-mark detecting optical system used are similar to those of the first embodiment, but the processing for calculating the alignment-mark position information differs from that of the first embodiment. FIG. 13 illustrates an enlargement of part of the image information of FIG. 5. This shows a template having symmetry in which the left half of the detection signal waveform has been folded over from the center of the horizontal axis.

$$E ( X ) = \frac{1}{{\sum }_{J = a}^{b} \vert S ( X + J ) - S ( X + J ) \vert} \qquad ( 10 )$$

Equation (10) above is a correlation value that prevails when the left half of the detection signal waveform is regarded as a template having the above-mentioned symmetry. Position information exhibiting the highest correlation is detected as the center position of an alignment mark. By obtaining position information of a centroid pixel of an area of several pixels to the left and right of a peak pixel in a function of correlation values illustrated, a resolution of 1/10 to 1/50 pixel can be achieved. In Equation (10) and FIG. 13, position C of a processing window and width W of the processing window can be used as variables in place of the coefficients a and b. That is, the relations

a=C−W/2, b=C−W/2 hold.

Similarly, in regard to the image information representing the three other alignment marks, the image information concerning each mark is detected. Thereafter, the average position Xa(n) of each alignment mark is calculated from Equation (2) above, and the deviation Xw(n) in the position of the alignment mark on the wafer is calculated from Equation (3) above. In this embodiment, the positional deviation Xw(n) of the alignment mark is obtained over a plurality of window widths W with respect to the alignment-mark image information acquired as set forth above and the deviation is stored temporarily in the memory within the signal processor 16. A detection signal is acquired for all sample shots, the AGA parameters (Sx, Sy, θx, θy, Bx, By) are found by substituting the position information (xi,yi) of each sample shot and the alignment-mark designed position (Xi,Yi) into Equations (8) and (9) cited above, and the residual error Ri is found from Equation (7) above. These calculations are performed with regard to all sample shots and the processing window width W and the results of these calculations are stored in memory classified according to combination number.

Next, a combination number that will minimize the residual error is selected, positioning of each shot is performed based upon these AGA parameters, and the pattern on the reticle is transferred to the wafer by exposure.

It should be noted that signal processing in which the processing window width W is adopted as the variable has been illustrated as an example of signal processing different from that of the first embodiment. However, the position C of the window may be adopted as the variable and positional deviation may be detected using a plurality of window positions, or the two variables of (C,W) may be used as variables simultaneously.

Thus, by obtaining a combination of a shot and signal processing that will minimize the residual error Ri, optimum positioning is selected automatically in dependence upon each shot on the wafer and it is possible to reduce alignment-mark detection error in the wafer process.

[Third Embodiment]

A method of detecting alignment-mark position according to a third embodiment will be described next.

The shape of the alignment mark and the alignment-mark detecting optical system used are similar to those of the first embodiment, but the processing for calculating the alignment-mark position information differs from that of the first and second embodiments.

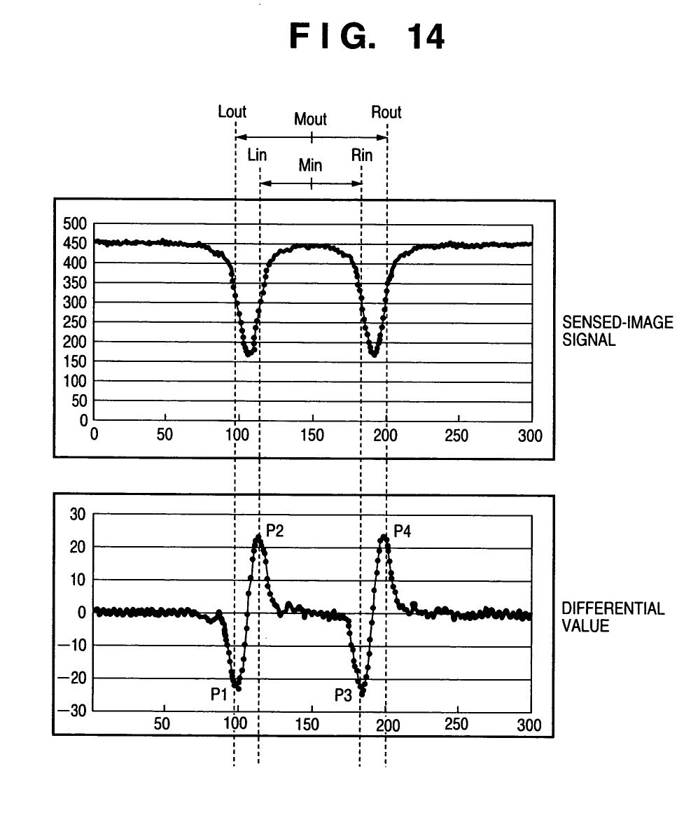

FIG. 14 is a diagram useful in describing signal processing of alignment-mark image information according to the third embodiment. Here alignment-mark position information is calculated based upon a position at which the waveform slope in the detection signal waveform is maximized.

First, the detection signal is differentiated in the direction of detection. Here the slope of the waveform is found in an area of a total of five pixels, namely each pixel ±2 pixels. In the differentiated signal, a total of four extremal values, namely two on the plus side and two on the minus side, are produced. In a case where positions (P1, P2, P3, P4) of the extremal values are calculated, a functional approximation is carried out using several pixel's worth of the differentiated signal from the pixels indicating respective ones of the extremal values, thereby making it possible to detect extremal-value position information at a resolution of 1/10 to 1/50 pixel. The extremal value P1 obtained by the differentiated signal corresponds to a maximum-slope position Lout outside the signal on the left side, P2 corresponds to a maximum-slope position Lin inside the signal on the left side, P3 corresponds to a maximum-slope position Rin inside the signal on the right side, and P4 corresponds to a maximum-slope position Rout outside the signal on the right side. Accordingly, alignment-mark position information using the signal slope on the outer side can be calculated by calculating the center position Mout=(Lout+Rout)/2 of the Lout position and Rout position found from the signal slope on the outer side.

Similarly, alignment-mark position information using the signal slope on the inner side can be calculated by calculating the center position Min=(Lin+Rin)/2 of the Lin position and Rin position found from the signal on the inner side. Thus, two types of calculated results of position information Mout, Min can be calculated from alignment-mark image information by two different types of signal processing from one alignment-mark detection signal. Since the alignment mark is constituted by four marks, as shown in FIG. 3 or 4, the items of image information of respective ones of the marks are subjected to signal processing similarly and the average position Xa(n) of the four marks is found from Equation (2). Here n is 1 or 2, where 1 corresponds to the result obtained from Mout and 2 corresponds to the result obtained from Min. Next, the deviation Xw(n) in the position of the alignment mark 30 on the wafer is calculated from Equation (3) above. A detection signal is acquired for all sample shots, the AGA parameters (Sx, Sy, θx, θy, Bx, By) are found by substituting the position information (xi,yi) of each sample shot and the alignment-mark designed position (Xi,Yi) into Equations (8) and (9) cited above, and the residual error Ri is found from Equation (7) above. These calculations are performed with regard to all sample shot and the results of these calculations are stored in memory classified according to combination number.

Next, a combination number that will minimize the residual error is selected, positioning of each shot is performed based upon these AGA parameters, and the pattern on the reticle is transferred to the wafer by exposure.

It should be noted that in the signal processing of the four marks, this embodiment uses the average position of each mark found from the signal slope on the outer side and the average position of each mark found from the signal slope on the inner side. When the average position is found, however, the average position Xa(n) of a combination of the signal slope on the outer side and the signal slope on the inner side may be used for each of the four marks. The number of signal processing operations in this case will be 16.

Thus, by obtaining a combination of a shot and signal processing that will minimize the residual error Ri of AGA, optimum positioning is selected automatically in dependence upon the shot on the wafer and alignment-mark detection error ascribable to the wafer process is reduced.

According to this embodiment, as described above, when position information of an alignment mark among a plurality of sample shots on a wafer is calculated, the position information is calculated using a plurality of signal processing operations and a combination of sample shot and signal processing that will minimize the residual error Ri of AGA is found.

A process for manufacturing a semiconductor device utilizing the semiconductor exposure apparatus set forth above will now be described.

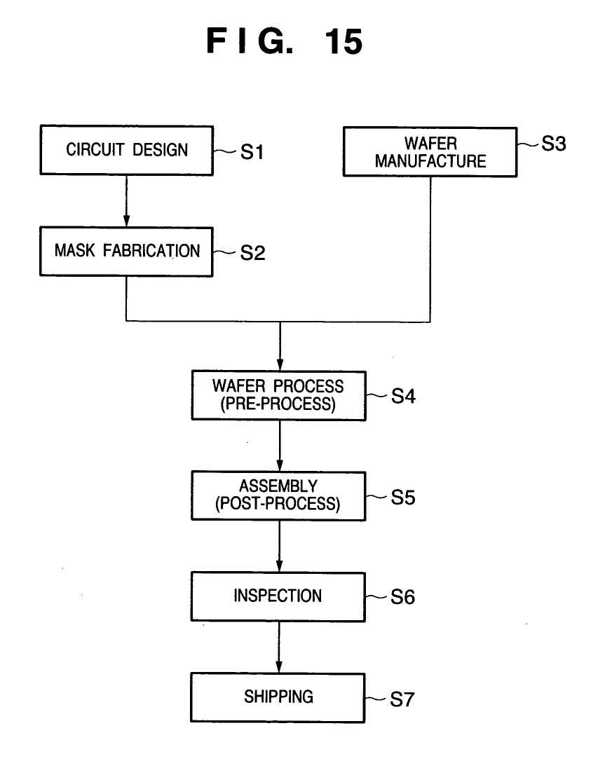

FIG. 15 illustrates the overall flow of a process for manufacturing a semiconductor device. The circuit for the device is designed at step S1 (circuit design). A mask on which the designed circuit pattern has been formed is fabricated at step S2 (mask fabrication). Meanwhile, a wafer is manufactured using a material such as silicon or glass at step S3 (wafer manufacture). The actual circuit is formed on the wafer by lithography, using the mask and wafer that have been prepared, at step S4 (wafer process), which is also referred to as “pre-treatment”. A semiconductor chip is obtained, using the wafer fabricated at step S4, at step S5 (assembly), which is also referred to as “post-treatment”. This step includes steps such as assembly (dicing and bonding) and packaging (chip encapsulation). The semiconductor device fabricated at step S5 is subjected to inspections such as an operation verification test and durability test at step S6 (inspection). The semiconductor device is completed through these steps and then is shipped (step S7). The pre- and post-treatments are performed at separate special-purpose plants. Maintenance is carried out on a per-plant basis by the above-described remote maintenance system. Further, information for production management and equipment maintenance is communicated by data communication between the pre- and post-treatment plants via the Internet or leased-line network.

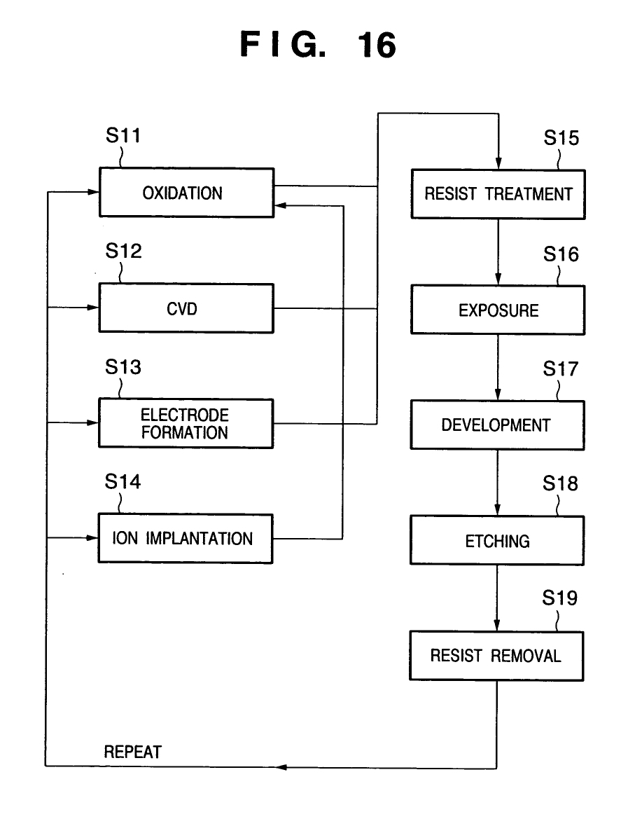

FIG. 16 is a flowchart illustrating the detailed flow of the wafer process mentioned above. The surface of the wafer is oxidized at step S1 (oxidation). An insulating film is formed on the wafer surface at step S12 (CVD), electrodes are formed on the wafer by vapor deposition at step S13 (electrode formation), and ions are implanted in the wafer at step S14 (ion implantation). The wafer is coated with a photoresist at step S15 (resist treatment), the wafer is exposed to the circuit pattern of the mask to print the pattern onto the wafer by the above-described exposure apparatus at step S16 (exposure), and the exposed wafer is developed at step S17 (development). Portions other than the developed photoresist are etched away at step S18 (etching), and unnecessary resist left after etching is performed is removed at step S19 (resist removal). Multiple circuit patterns are formed on the wafer by implementing these steps repeatedly.

The present invention is not limited to the above embodiments and various changes and modifications can be made within the spirit and scope of the present invention. Therefore, to apprise the public of the scope of the present invention, the following claims are made.

What is claimed is:

1. A position detection method for detecting the position of an object upon receiving light from a plurality of position detection marks on the object, comprising:
an image information acquisition step of obtaining image information of every position detection mark from the light that has been received;
a position information calculation step, which has a plurality of calculation processes, of calculating position information of every position detection mark from the image information using a prescribed calculation process among the plurality of calculation processes;
an error information calculation step of calculating information representing an error of a position detection mark, which corresponds to each item of the position information, with respect to a reference position;
a residual-error information calculation step of calculating information representing a residual error that is the result of eliminating a prescribed error component from the information representing the error;
a storage step of obtaining, for each item of the position information, a calculation process, from among the plurality of calculation processes, for calculating pertinent position information that will minimize the residual error, and storing a combination of this position information and calculation process that corresponds thereto; and
a position detection step of detecting the position of the object using information representing an error calculated based upon the combination of the position information and the calculation process that corresponds thereto.

2. The method according to claim 1, wherein if x and y directions are taken as mutually orthogonal directions having the reference position as the origin thereof, the information representing the error is represented, as a deviation in the position of the position detection mark from the reference position, by shift Sx in the x direction, shift Sy in the y direction, inclination θx with respect to the x axis, inclination θy with respect to the y axis, magnification Bx along the x direction and magnification By along the y direction, and the prescribed error component is obtained in accordance with the following equation:
$${D}^{′} i = ( \begin{matrix}B x & - θ y \\ θ x & B y\end{matrix} ) D i + ( \begin{matrix}S x \\ S y\end{matrix} )$$

3. The method according to claim 1, wherein said storage step obtains a calculation process for which the mean sum of the squares of the residual error will be minimized.

4. The method according to claim 1, wherein the plurality of calculation processes calculate the position information by matching image information with a template that exhibits maximum correlation from among a plurality of different templates.

5. The method according to claim 4, wherein the image information includes image information having two minimal values conforming to both ends of a position detection mark and image information having a minimal value only in the vicinity of the center of the single position detection mark, a template conforming to each item of image information being provided.

6. The method according to claim 1, wherein the template has a plurality of templates having symmetry in relation to direction in which the position detection mark is detected.

7. The method according to claim 1, wherein the calculation processes include any two or more of a method of matching image information with the template, a method of calculating position information from centroid-position information of pixels in the image information, and a method of calculating position information from a differential value of the image information.

8. A position detection apparatus for detecting the position of an object upon receiving light from a plurality of position detection marks on the object, comprising:
an image information acquisition unit for obtaining image information of every position detection mark from the light that has been received;
a position information calculation unit, which has a plurality of calculation processes, for calculating position information of every position detection mark from the image information using a prescribed calculation process among the plurality of calculation processes;
an error information calculation unit for calculating information representing an error of a position detection mark, which corresponds to each item of the position information, with respect to a reference position;
a residual-error information calculation unit for calculating information representing a residual error that is the result of eliminating a prescribed error component from the information representing the error;
a storage unit for finding, for each item of the position information, a calculation process, from among the plurality of calculation processes, for calculating pertinent position information that will minimize the residual error, and storing a combination of this position information and calculation process that corresponds thereto; and
a position detection unit for detecting the position of the object using information representing an error calculated based upon the combination of the position information and the calculation process that corresponds thereto.

9. An exposure apparatus having a stage device driven in order to position the object based upon position information detected by the position detection apparatus set forth in claim 8;
said stage device positioning a substrate or a reticle or both as the object.
